(19) United States
(12) Patent Application Publication
(10) Pub. No.: US 2022/0115624 A1
(43) Pub. Date: Apr. 14, 2022

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Yijia WANG, Wuhan (CN)

(21) Appl. No.: 17/265,142

(22) PCT Filed: Jun. 23, 2020
(86) PCT No.: PCT/CN2020/097781

§ 371 Date: Feb. 1, 2021

(30) Foreign Application Priority Data
Apr. 29, 2020 (CN) 202010353420.3

(51) Int. Cl. H01L 51/52; H01L 27/32; H01L 51/00

(52) U.S. Cl. CPC H01L 51/5253; H01L 27/323; H01L 2251/5392; H01L 51/0097; H01L 2251/5338; H01L 27/3246

(57) ABSTRACT

Embodiments of the present application provide a display panel and a display device. In the present application, since the retaining wall has a first layer and a second layer, the second layer is disposed on the first layer, and a width of the first layer is greater than a width of the second layer, organic materials in the encapsulation layer can be prevented from overflowing the retaining wall, thereby flattening a top of the retaining wall, such that when the touch layer is disposed on the retaining wall, short circuit is not easy to occur.

### BACKGROUND OF INVENTION

### Field of Invention

The present application relates to a field of display technology, in particular to a display panel and a display device.

### Description of Prior Art

Flexible OLED displays are currently a popular development direction in the display industry due to their low power consumption, high resolution, fast response, and flexibility. Regarding thin-film packaging designs of flexible OLED devices, a laminated structure of organic/inorganic films is generally adopted to achieve the purposes of blocking water and oxygen, particle encapsulation, and stress relief. At present, the manufacturing process of the organic film in thin film packaging is generally employs deposition. In order to prevent the organic film from overflowing out of an area covered by the inorganic film, one or more layers of retaining wall (dam) are often designed.

A touch layer includes an insulating layer and a metal layer, and the layer under the metal layer is required to be flat, otherwise, over-etching may occur when the metal layer is etched, resulting in a short circuit. However, there is often a phenomenon that the organic film does not flow to the retaining wall or a phenomenon of a too large difference in the thickness of the organic layer near the retaining wall which is likely to cause a phenomenon of short circuit.

### SUMMARY OF INVENTION

Embodiments of the present application provide a display panel and a display device, which can reduce the phenomenon of short circuit in the metal trace layer.

The present application provides a display panel, including:

a substrate having a first surface and a second surface opposite to each other;

a retaining wall disposed on the first surface and including a first layer and a second layer, wherein the first layer is disposed on the first surface, the second layer is disposed on a side of the first layer away from the substrate, a width of the first layer is greater than a width of the second layer, and inner sides of the first layer and the second layer are formed into a stepped surface;

a planarization layer disposed on the first surface and located inside the retaining wall;

a pixel definition layer disposed on a side of the planarization layer away from the substrate;

a light-emitting layer disposed on the side of the planarization layer away from the substrate;

an encapsulation layer covering a side of the pixel definition layer, the retaining wall, and the light-emitting layer away from the substrate; and

a touch layer disposed on a side of the encapsulation layer away from the substrate, wherein the touch layer includes a metal trace layer.

In some embodiments, the first layer is a planarization layer, and the second layer is any one or more of a planarization layer, a pixel definition layer, and a support layer of a mask.

In some embodiments, the first layer forms a plurality of deflector columns extending toward inside of the retaining wall, and the deflector columns are integrally formed with the first layer.

In some embodiments, the deflector columns are evenly arranged along the retaining wall.

In some embodiments, an inwardly extending length of the deflector columns at a corner of the retaining wall is greater than an inwardly extending length of the deflector columns at an inner side wall of the retaining wall.

In some embodiments, the retaining wall includes a first sub-retaining wall and a second sub-retaining wall, the first sub-retaining wall is disposed on the first surface, and the second sub-retaining wall is disposed on the first surface and sleeves an outer periphery of the first sub-retaining wall.

In some embodiments, the retaining wall has a shape of wavy or zigzag.

In some embodiments, the encapsulation layer includes a first vapor deposition layer, an inkjet printing layer, and a second vapor deposition layer, the first vapor deposition layer covers surfaces of the pixel definition layer, the retaining wall, and the light-emitting layer away from the substrate, the inkjet printing layer is disposed on a surface of the first vapor deposition layer away from the substrate, and the second vapor deposition layer is disposed on a surface of the inkjet printing layer away from the first vapor deposition layer.

In some embodiments, a surface of the pixel definition layer away from the substrate is provided with a groove, and the light-emitting layer is disposed in the groove.

In some embodiments, the retaining wall includes at least two layers.

Another embodiment of the present application further provides a display device, including a display panel, the display panel including:

a substrate having a first surface and a second surface opposite to each other;

a retaining wall disposed on the first surface and including a first layer and a second layer, wherein the first layer is disposed on the first surface, the second layer is disposed on a side of the first layer away from the substrate, a width of the first layer is greater than a width of the second layer, and inner sides of the first layer and the second layer are formed into a stepped surface;

a planarization layer disposed on the first surface and located inside the retaining wall;

a pixel definition layer disposed on a side of the planarization layer away from the substrate;

a light-emitting layer disposed on the side of the planarization layer away from the substrate;

an encapsulation layer covering a side of the pixel definition layer, the retaining wall, and the light-emitting layer away from the substrate; and

a touch layer disposed on a side of the encapsulation layer away from the substrate, wherein the touch layer includes a metal trace layer.

In some embodiments, the first layer is a planarization layer, and the second layer is any one or more of a planarization layer, a pixel definition layer, and a support layer of a mask.

In some embodiments, the first layer forms a plurality of deflector columns extending toward inside of the retaining wall, and the deflector columns are integrally formed with the first layer.

In some embodiments, the deflector columns are evenly arranged along the retaining wall.

In some embodiments, an inwardly extending length of the deflector columns at a corner of the retaining wall is greater than an inwardly extending length of the deflector columns at an inner side wall of the retaining wall.

In some embodiments, the retaining wall includes a first sub-retaining wall and a second sub-retaining wall, the first sub-retaining wall is disposed on the first surface, and the second sub-retaining wall is disposed on the first surface and sleeves an outer periphery of the first sub-retaining wall.

In some embodiments, the retaining wall has a shape of wavy or zigzag.

In some embodiments, the encapsulation layer includes a first vapor deposition layer, an inkjet printing layer, and a second vapor deposition layer, the first vapor deposition layer covers surfaces of the pixel definition layer, the retaining wall, and the light-emitting layer away from the substrate, the inkjet printing layer is disposed on a surface of the first vapor deposition layer away from the substrate, and the second vapor deposition layer is disposed on a surface of the inkjet printing layer away from the first vapor deposition layer.

In some embodiments, a surface of the pixel definition layer away from the substrate is provided with a groove, and the light-emitting layer is disposed in the groove.

In some embodiments, the retaining wall includes at least two layers.

Embodiments of the present application provides a display panel and a display device. The display panel includes a substrate, a retaining wall, a planarization layer, a pixel definition layer, a light-emitting layer, an encapsulation layer, and a touch layer. The substrate has a first surface and a second surface opposite to each other; the retaining wall is disposed on the first surface and including a first layer and a second layer, wherein the first layer is disposed on the first surface, the second layer is disposed on a side of the first layer away from the substrate, a width of the first layer is greater than a width of the second layer, and inner sides of the first layer and the second layer are formed into a stepped surface; the planarization layer is disposed on the first surface and located inside the retaining wall; the pixel definition layer is disposed on a side of the planarization layer away from the substrate; the light-emitting layer is disposed on the side of the planarization layer away from the substrate; the encapsulation layer covers a side of the pixel definition layer, the retaining wall, and the light-emitting layer away from the substrate; and the touch layer is disposed on a side of the encapsulation layer away from the substrate, wherein the touch layer includes a metal trace layer. In the present application, since the retaining wall has a first layer and a second layer, the second layer is disposed on the first layer, and a width of the first layer is greater than a width of the second layer, organic materials in the encapsulation layer can be prevented from overflowing the retaining wall, thereby flattening a top of the retaining wall, such that when the touch layer is disposed on the retaining wall, short circuit is not easy to occur.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a display panel according to a related embodiment.

FIG. 2 is a plan view of a display panel according to a first embodiment of the present application.

FIG. 3 is a cross-sectional view of the display panel along the A-A line in FIG. 2 according to an embodiment of the present application.

FIG. 4 is a top view of the display panel according to a second embodiment of the present application.

FIG. 5 is a side view of the display panel along the B-B line in FIG. 4 according to an embodiment of the present application.

FIG. 6 is a top view of the display panel according to a third embodiment of the present application.

FIG. 7 is a top view of the display panel according to a fourth embodiment of the present application.

FIG. 8 is a plan view of the display panel according to a fifth embodiment of the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

It should be noted that, in the description of the present application, it should be understood that the terms “upper”, “lower”, “front”, “back”, “left”, “right”, “inner”, “outer”, and the like are based on the orientation or positional relationship shown in the drawings, and is merely for the convenience of describing the present invention and simplifying the description, and does not indicate or imply that the indicated devices or components must to be in particular orientations, or constructed and operated in a particular orientation, and thus are not to be construed as limiting the invention.

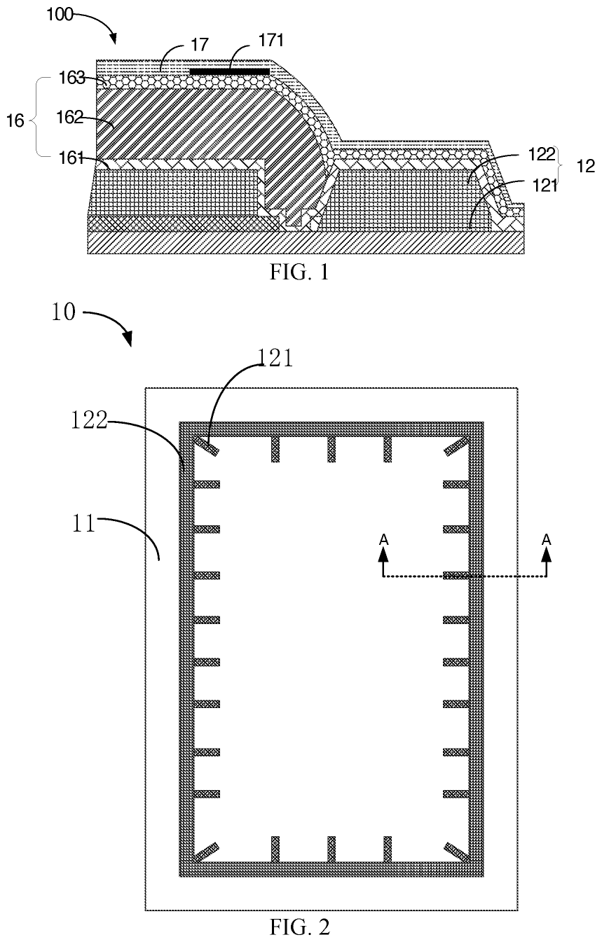

A related embodiment provides a display panel 100, referring to FIG. 1, where thinning and flexibility of devices are the mainstream development direction of the display industry, so the touch layer 17 will be directly prepared above the encapsulation layer 16. The touch layer 17 includes an insulating layer and a metal layer 171, and the layer under the metal layer 171 is required to be flat, otherwise, over-etching may occur when the metal layer is etched, resulting in a short circuit. However, there is often a phenomenon that the organic film does not flow to the retaining wall 12 or a phenomenon of a too large difference in the thickness of the organic layer near the retaining wall 12 which may greatly increase the risk of short circuits.

Embodiments of the present application provide a display panel and a display device. The display panel will be described in detail below.

Referring to FIGS. 2 and 3. FIG. 2 is a top view of the display panel 10 according to a first embodiment of the present application. FIG. 3 is a cross-sectional view of the display panel 10 according to an embodiment of the present application. The display panel 10 includes a substrate 11, a barrier wall 12, a planarization layer 13, a pixel definition layer 14, a light-emitting layer 15, an encapsulation layer 16, and a touch layer 17. The substrate 11 has a first surface 11a and a second surface 11b opposite to each other. The retaining wall 12 is disposed in a circle on the first surface 11a. The retaining wall 12 includes a first layer 121 and a second layer 122. The first layer 121 is disposed on the first surface 11a. The second layer 122 is disposed on a side of the first layer 121 away from the substrate 11, a width of the first layer 121 is greater than a width of the second layer 122, and inner sides of the first layer 121 and the second layer 122 are formed into a stepped surface. The planarization layer 13 is disposed on the first surface 11a, and is located inside the retaining wall 12, the pixel definition layer 14 is disposed on a surface of the planarization layer 13 away from the substrate 11, the light-emitting layer 15 is disposed on the side of the planarization layer 13 away from the substrate 11, and the encapsulation layer 16 covers a side of the pixel definition layer 14, the barrier wall 12, and the light-emitting layer 15 away from the substrate 11. The touch layer 17 is disposed on a side of the encapsulation layer 16 away from the substrate 11. The touch layer 17 includes a metal trace layer 171.

It should be noted that the first surface 11 a may be an upper surface of the substrate 11, and the second surface 11b may be a lower surface of the substrate 11. Of course, the first surface 11a may also be the lower surface of the substrate 11, and the second surface 11b may be the upper surface of the substrate 11. In the case of no special description in the embodiments of the present application, the first surface 11a is the upper surface of the substrate 11 and the second surface 11b is the lower surface of the substrate 11 by default. In addition, the substrate 11 in the embodiments of the present application is an array substrate 11.

The retaining wall 12 is provided on the first surface 11a, and the retaining wall 12 can prevent the organic film from overflowing out of an area covered by the inorganic film. The retaining wall 12 may be constituted by at least two layers. For example, the retaining wall 12 may be constituted by two layers, three layers, four layers, or multiple layers. In addition, parylene polymer may be used for the retaining wall 12. At the same time, a number of layers of the retaining wall 12 is multiple, for example, two-layered retaining wall 12, three-layered retaining wall 12, or even more-layered retaining wall 12. Such multi-layered retaining wall 12 can further prevent the organic liquid from overflowing the retaining wall 12. Meanwhile, in the structure of the multi-layered retaining wall 12, the structure of the multi-layered retaining wall 12 is a stacked structure, and a width of the retaining wall 12 on the side close to the substrate 11 is greater than the width of the retaining wall 12 on the side away from the substrate 11, in order to make the retaining wall 12 form a stepped surface to form a flow guiding structure for organic liquid, and prevent the organic liquid from overflowing the retaining wall 12.

In addition, the retaining wall 12 is ring-shaped. Of course, the retaining wall 12 may have a shape of a rectangular ring, a square ring, an oval ring, or the like. The shape of the specific retaining wall 12 can be determined according to the specific structure of the panel.

The planarization layer 13 may include multiple layers, for example, the planarization layer 13 may include two layers, three layers, or even more layers. The number of layers of the planarization layer 13 is not particularly limited in embodiment of the present application.

The light-emitting layer 15 may use miniature light-emitting diodes as the light-emitting layer 15. Of course, other light sources can also be used as the light-emitting layer 15, which is not particularly limited in embodiment of the present application.

The pixel definition layer 14 is provided with a groove 141 on a side of the pixel definition layer 14 away from the substrate 11, and the light-emitting layer 15 is disposed in the groove 141.

The encapsulation layer 16 may be an encapsulation film and may use an inorganic layer with water and oxygen barrier properties, for example, SiNx, SiOxNy, SiOx, SiCNx, AlOx, and/or TiO. Of course, the encapsulation layer 16 may also adopt a multi-layered structure, for example, a thin-film encapsulation structure constituted of an inorganic layer and an organic layer.

The encapsulation layer 16 includes a first vapor deposition layer 161, an inkjet printing layer 162 and a second vapor deposition layer, wherein the first vapor deposition layer 161 covers a side of the pixel definition layer 14, the retaining wall 12, and the light-emitting layer 15 away from the substrate 11, the inkjet printing layer 162 is disposed on a side of the first vapor deposition layer 161 away from the substrate 11, and the second vapor deposition layer 163 is disposed on a side of the inkjet printing layer 162 away from the first vapor deposited layer 161.

The touch layer 17 includes an insulating layer and a metal trace layer 171.

The first layer 121 is the planarization layer 13, and the second layer 122 is any one or more of a planarization layer, the pixel definition layer 14, and a support layer of a mask. For example, the retaining wall 12 includes a first layer 121 and a second layer 122, the first layer 121 is a planarization layer 13, and the second layer 122 is a pixel definition layer 14. It can be understood that the retaining wall 12 may also include a first layer 121, a second layer 122, and a third layer. For example, the first layer 121 is a planarization layer 13, the second layer 122 is a pixel definition layer 14, and the third layer is a support layer of a mask. Of course, the retaining wall 12 can also be changed in various lamination structures as needed. Details are not repeated in the embodiments of the present application for brevity.

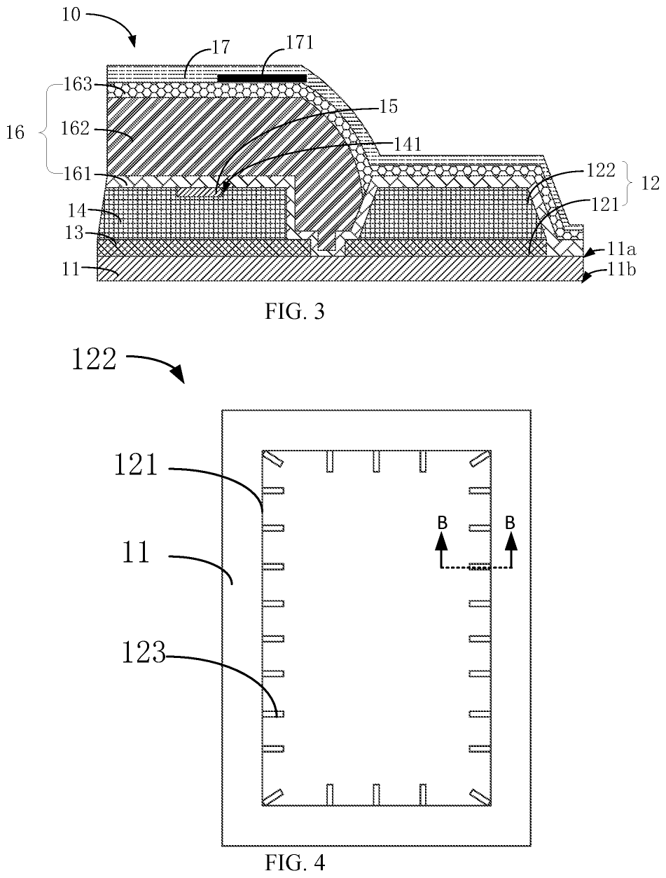

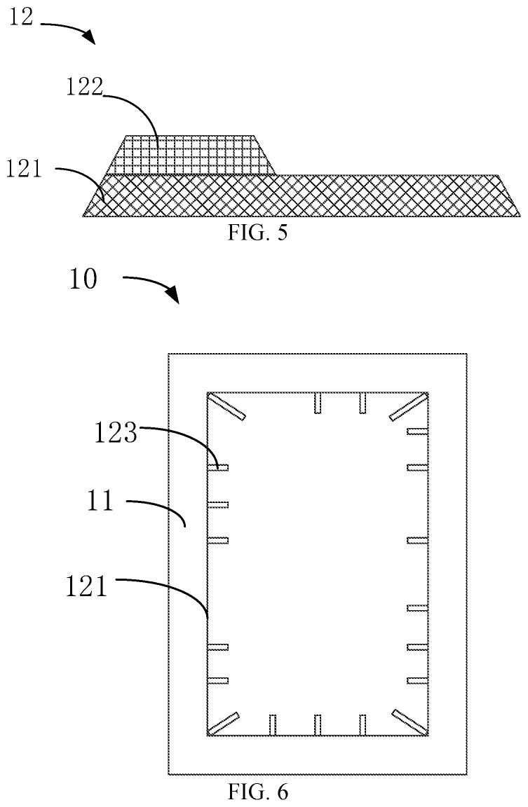

Referring to FIG. 4 and FIG. 5, FIG. 4 is a top view of the display panel 10 according to a second embodiment of the present application, and FIG. 5 is a side view of the display panel 10 according to the second embodiment of the present application. The first layer 121 forms a plurality of deflector columns extending 123 toward inside of the retaining wall 12, and the deflector columns 123 can drain the organic liquid to prevent the organic liquid from overflowing the retaining wall 12.

The deflector columns 123 are evenly distributed along the retaining wall 12. It can be understood that, the number of the deflector columns 123 may be designed as multiple as needed. In an embodiment of the present application, the number of deflector columns 123 is not limited. In addition, the deflector column 123 and the first layer 121 are integrally formed. Specifically, it can be formed by processes such as exposure and development.

Referring to FIG. 6, which is a top view of the display panel 10 according to a third embodiment of the present application. An inwardly extending length of the deflector columns 123 at a corner of the retaining wall 12 is greater than an inwardly extending length of the deflector columns 123 at an inner side wall of the retaining wall 12.

It can be understood that, relative long ones of deflector columns 123 are provided at the corners of the retaining wall 12, so as to prevent organic liquid from overflowing the retaining wall 12 from the corners, which further ensures that an outer surface of the retaining wall 12 is flat, and avoids short circuit of the metal trace layer 171 in the touch layer 17.

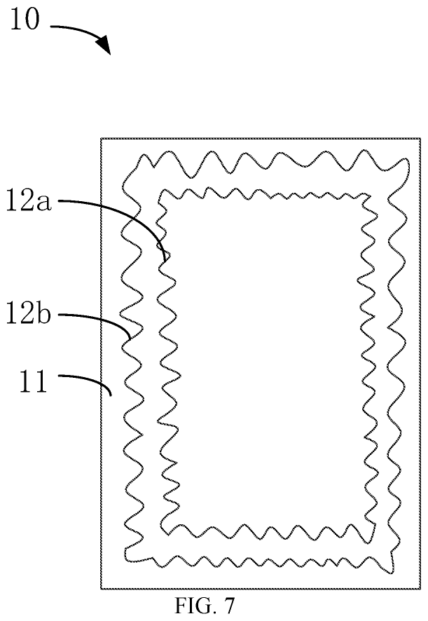

Referring to FIG. 7, which is a top view of the display panel 10 according to a fourth embodiment of the present application, wherein, the retaining wall 12 includes a first sub-retaining wall 12a and a second sub-retaining wall 12b, the first sub-retaining wall 12a is disposed on the first surface 11a, and the second sub-retaining wall 12b is disposed on the first surface 11a and sleeves an outer periphery of the first sub-retaining wall 12a.

It can be understood that the retaining wall 12 may further include a third sub-retaining wall 12, a fourth sub-retaining wall 12, and the like. A number of layers of the retaining wall 12 is not particularly limited herein. The multi-layered retaining wall 12 is configured to further prevent the organic liquid from overflowing the retaining wall 12.

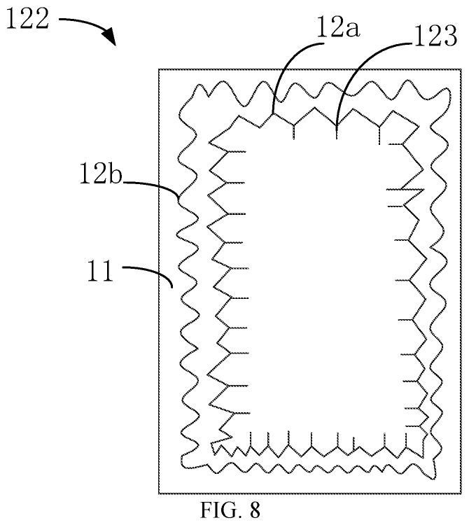

The retaining wall 12 has a shape of wavy or zigzag. Referring to FIG. 8, the first sub-retaining wall 12a adopts a zigzag shape, and the second sub-retaining wall 12b adopts a wave shape. It can be understood that the shape of the retaining wall 12 can also adopt other shapes, for example, continuous square concaves and convexes. The retaining wall 12 of the present application adopts a wave shape or a zigzag shape, such that the contact range of the retaining wall 12 with the organic liquid can be increased, and more organic liquid can be further restricted from overflowing.

Embodiments of the present application provides a display panel 10 and a display device 100. The display panel 10 includes a substrate 11, a retaining wall 12, a planarization layer 13, a pixel definition layer 14, a light-emitting layer 15, an encapsulation layer 16, and a touch layer 17. The substrate 11 has a first surface 11a and a second surface 11b opposite to each other; the retaining wall 12 is disposed on the first surface 11a and including a first layer 121 and a second layer 122, wherein the first layer 121 is disposed on the first surface 11a, the second layer 122 is disposed on a side of the first layer 121 away from the substrate 11, a width of the first layer 121 is greater than a width of the second layer 122, and inner sides of the first layer 121 and the second layer 122 are formed into a stepped surface; the planarization layer 13 is disposed on the first surface 11a and located inside the retaining wall 12; the pixel definition layer 14 is disposed on a side of the planarization layer 13 away from the substrate 11; the light-emitting layer 15 is disposed on the side of the planarization layer 13 away from the substrate 11; the encapsulation layer 16 covers a side of the pixel definition layer 14, the retaining wall 12, and the light-emitting layer 15 away from the substrate 11; and the touch layer 17 is disposed on a side of the encapsulation layer 16 away from the substrate 11, wherein the touch layer 17 includes a metal trace layer 171. In the present application, since the retaining wall 12 has a first layer 121 and a second layer 122, the second layer 122 is disposed on the first layer 121, and a width of the first layer 121 is greater than a width of the second layer 122, organic materials in the encapsulation layer 16 can be prevented from overflowing the retaining wall 12, thereby flattening a top of the retaining wall 12, such that when the touch layer 17 is disposed on the retaining wall 12, short circuit is not easy to occur.

The display device 100 according to an embodiment of the present application includes a display panel 10, wherein the display panel 10 is the above-mentioned display panel 10, and the above embodiment has described the display panel 10 in detail. Therefore, in the embodiment of the present application, details of the display panel 10 is not repeated for brevity.

It can be understood that, because the present application uses the display panel 10 in the above embodiments, since the retaining wall 12 has a first layer 121 and a second layer 122, the second layer 122 is disposed on the first layer 121, and a width of the first layer 121 is greater than a width of the second layer 122, organic materials in the encapsulation layer 16 can be prevented from overflowing the retaining wall 12, thereby flattening a top of the retaining wall 12, such that when the touch layer 17 is disposed on the retaining wall 12, short circuit is not easy to occur.

The display panel and the display device according to the embodiments of the present application are described in detail above. Specific examples are used to explain the principle and implementation of the present application. The descriptions of the above embodiments are only used to help understand the present application. Also, for those skilled in the art, according to the ideas of the present application, there will be changes in the specific implementation and application scope. In summary, the content of this specification should not be construed as limiting the present application.

What is claimed is:

1. A display panel, comprising:
a substrate having a first surface and a second surface opposite to each other;
a retaining wall disposed on the first surface and comprising a first layer and a second layer, wherein the first layer is disposed on the first surface, the second layer is disposed on a side of the first layer away from the substrate, a width of the first layer is greater than a width of the second layer, and inner sides of the first layer and the second layer are formed into a stepped surface;
a planarization layer disposed on the first surface and located inside the retaining wall;
a pixel definition layer disposed on a side of the planarization layer away from the substrate;
a light-emitting layer disposed on the side of the planarization layer away from the substrate;
an encapsulation layer covering a side of the pixel definition layer, the retaining wall, and the light-emitting layer away from the substrate; and
a touch layer disposed on a side of the encapsulation layer away from the substrate, wherein the touch layer comprises a metal trace layer.

2. The display panel according to claim 1, wherein the first layer is a planarization layer, and the second layer is any one or more of a planarization layer, a pixel definition layer, and a support layer of a mask.

3. The display panel according to claim 1, wherein the first layer forms a plurality of deflector columns extending toward inside of the retaining wall, and the deflector columns are integrally formed with the first layer.

4. The display panel according to claim 3, wherein the deflector columns are evenly arranged along the retaining wall.

5. The display panel according to claim 3, wherein an inwardly extending length of the deflector columns at a corner of the retaining wall is greater than an inwardly extending length of the deflector columns at an inner side wall of the retaining wall.

6. The display panel according to claim 1, wherein the retaining wall comprises a first sub-retaining wall and a second sub-retaining wall, the first sub-retaining wall is disposed on the first surface, and the second sub-retaining wall is disposed on the first surface and sleeves an outer periphery of the first sub-retaining wall.

7. The display panel according to claim 6, wherein the retaining wall has a shape of wavy or zigzag.

8. The display panel according to claim 1, wherein the encapsulation layer comprises a first vapor deposition layer, an inkjet printing layer, and a second vapor deposition layer, the first vapor deposition layer covers surfaces of the pixel definition layer, the retaining wall, and the light-emitting layer away from the substrate, the inkjet printing layer is disposed on a surface of the first vapor deposition layer away from the substrate, and the second vapor deposition layer is disposed on a surface of the inkjet printing layer away from the first vapor deposition layer.

9. The display panel according to claim 1, wherein a surface of the pixel definition layer away from the substrate is provided with a groove, and the light-emitting layer is disposed in the groove.

10. The display panel according to claim 1, wherein the retaining wall comprises at least two layers.

11. A display device, comprising a display panel, the display panel comprising:
a substrate having a first surface and a second surface opposite to each other;
a retaining wall disposed on the first surface and comprising a first layer and a second layer, wherein the first layer is disposed on the first surface, the second layer is disposed on a side of the first layer away from the substrate, a width of the first layer is greater than a width of the second layer, and inner sides of the first layer and the second layer are formed into a stepped surface;
a planarization layer disposed on the first surface and located inside the retaining wall;
a pixel definition layer disposed on a side of the planarization layer away from the substrate;
a light-emitting layer disposed on the side of the planarization layer away from the substrate;
an encapsulation layer covering a side of the pixel definition layer, the retaining wall, and the light-emitting layer away from the substrate; and
a touch layer disposed on a side of the encapsulation layer away from the substrate, wherein the touch layer comprises a metal trace layer.

12. The display device according to claim 11, wherein the first layer is a planarization layer, and the second layer is any one or more of a planarization layer, a pixel definition layer, and a support layer of a mask.

13. The display device according to claim 11, wherein the first layer forms a plurality of deflector columns extending toward inside of the retaining wall, and the deflector columns are integrally formed with the first layer.

14. The display device according to claim 13, wherein the deflector columns are evenly arranged along the retaining wall.

15. The display device according to claim 13, wherein an inwardly extending length of the deflector columns at a corner of the retaining wall is greater than an inwardly extending length of the deflector columns at an inner side wall of the retaining wall.

16. The display device according to claim 11, wherein the retaining wall comprises a first sub-retaining wall and a second sub-retaining wall, the first sub-retaining wall is disposed on the first surface, and the second sub-retaining wall is disposed on the first surface and sleeves an outer periphery of the first sub-retaining wall.

17. The display device according to claim 16, wherein the retaining wall has a shape of wavy or zigzag.

18. The display device according to claim 11, wherein the encapsulation layer comprises a first vapor deposition layer, an inkjet printing layer, and a second vapor deposition layer, the first vapor deposition layer covers surfaces of the pixel definition layer, the retaining wall, and the light-emitting layer away from the substrate, the inkjet printing layer is disposed on a surface of the first vapor deposition layer away from the substrate, and the second vapor deposition layer is disposed on a surface of the inkjet printing layer away from the first vapor deposition layer.

19. The display device according to claim 11, wherein a surface of the pixel definition layer away from the substrate is provided with a groove, and the light-emitting layer is disposed in the groove.

20. The display device according to claim 11, wherein the retaining wall comprises at least two layers.
